(19) United States
(12) Patent Application Publication
(10) Pub. No.: US 2025/0202438 A1
(43) Pub. Date: Jun. 19, 2025

(54) PROTECTING CIRCUIT OF POWER AMPLIFIER, ADJUSTING METHOD OF SUPPLYING VOLTAGE AND ELECTRONIC DEVICE

(71) Applicant: Wistron NeWeb Corporation, Hsinchu (TW)

(72) Inventor: Chen-Shu PENG, Hsinchu (TW)

(21) Appl. No.: 18/974,999

(22) Filed: Dec. 10, 2024

(30) Foreign Application Priority Data
Dec. 19, 2023 (TW) 112149465

(51) Int. Cl. H03F 1/52; H03F 3/24

(52) U.S. Cl. CPC H03F 1/52; H03F 3/24; H03F 2200/465

(57) ABSTRACT

A protecting circuit of a power amplifier, which includes a power detecting module, a delay-controlling module, and a voltage transforming module, is proposed. The power detecting module detects a power voltage of a power supply. When the power voltage is less than a predetermined level, the power detecting module generates a trigger signal. The delay-controlling module is electrically connected to the power detecting module and receives the trigger signal. The delay-controlling module is triggered by the trigger signal to generate a plurality of delay signals. The voltage transforming module is electrically connected to the power supply and the delay-controlling module. The voltage transforming module receives the delay signals and is used to transform the power voltage of the power supply into a plurality of supplying voltages. The voltage transforming module sequentially inputs the supplying voltages to the power amplifier according to the delay signals.

### RELATED APPLICATIONS

This application claims priority to Taiwan Application Serial Number 112149465, filed Dec. 19, 2023, which is herein incorporated by reference.

### BACKGROUND

### Technical Field

The present disclosure relates to a protecting circuit, an adjusting method of supplying voltage, and an electronic device, and more particularly, to a protecting circuit of a power amplifier, an adjusting method of supplying voltage, and an electronic device.

### Description of Related Art

In the field of communication, power amplifiers (PA) used in Remote Radio Units (RRU) need to be driven by multiple supplying voltages. The multiple supplying voltages of the power amplifier need to drive and shut down different components in the power amplifier according to the sequence and interval specified in the product specification manual. However, when the RRU is powered off due to an abnormality in power supply system, the power amplifier may be burned out because it was not shut down according to the specified time sequence in the product specification manual.

In view of this, a protecting circuit of a power amplifier, an adjusting method of supplying voltage, and an electronic device that can ensure the power amplifier is started or shut down according to the specified sequence and interval have become a research and development goal for related industries.

### SUMMARY

One aspect of the present disclosure is to provide a protecting circuit of a power amplifier is provided, which includes a power detecting module, a delay-controlling module, and a voltage transforming module. The power detecting module is electrically connected to a power supply and detects a power voltage of the power supply. When the power voltage is less than a predetermined level, the power detecting module generates a trigger signal. The delay-controlling module is electrically connected to the power detecting module and receives the trigger signal. The delay-controlling module is triggered by the trigger signal to generate a plurality of delay signals. The voltage transforming module is electrically connected to the power supply and the delay-controlling module. The voltage transforming module receives the plurality of delay signals and is configured to transform the power voltage of the power supply into a plurality of supplying voltages. The voltage transforming module sequentially inputs the plurality of supplying voltages to the power amplifier according to the plurality of delay signals.

Another aspect of the present disclosure is to provide an adjusting method of supplying voltage, which includes a power detecting step, a delay-controlling step, a voltage transforming step, and a supplying voltage inputting step. The power detecting step includes driving a power detecting module to detect a power voltage of a power supply and generating a trigger signal when the power voltage is less than a predetermined level. The delay-controlling step includes driving a delay-controlling module to generate a plurality of delay signals according to the trigger signal. The voltage transforming step includes driving a voltage transforming module to transform the power voltage of the power supply into a plurality of supplying voltages. The supplying voltage inputting step includes driving the voltage transforming module to sequentially input the plurality of supplying voltages to a power amplifier according to the plurality of delay signals.

Yet another aspect of the present disclosure is to provide an electronic device, which includes a Field Programmable Gate Array (FPGA), a protecting circuit, and a power amplifier. The protecting circuit includes a power detecting module, a delay-controlling module, and a voltage transforming module. The power detecting module is electrically connected to a power supply and detects a power voltage of the power supply. When the power voltage is less than a predetermined level, the power detecting module generates a trigger signal. The delay-controlling module is electrically connected to the FPGA and the power detecting module and receives the trigger signal. The delay-controlling module is triggered by the trigger signal to generate a plurality of delay signals. The voltage transforming module is electrically connected to the power supply and the delay-controlling module. The voltage transforming module receives the plurality of delay signals and is configured to transform the power voltage of the power supply into a plurality of supplying voltages. The power amplifier is electrically connected to the voltage transforming module and includes a plurality of supplying voltage pins. The plurality of supplying voltage pins receive the plurality of supplying voltages, and the power amplifier is driven by the plurality of supplying voltages. The voltage transforming module sequentially inputs the plurality of supplying voltages to the plurality of supplying voltage pins according to the plurality of delay signals.

### BRIEF DESCRIPTION OF THE DRAWINGS

The present disclosure can be more fully understood by reading the following detailed description of the embodiment, with reference made to the accompanying drawings as follows:

FIG. 1 is a block diagram illustrating a protecting circuit of a power amplifier according to a first embodiment of the present disclosure.

FIG. 2 is a circuit diagram illustrating a power detecting module of the protecting circuit of the power amplifier according to FIG. 1.

FIG. 3 is a circuit diagram illustrating a delay-controlling module of the protecting circuit of the power amplifier according to FIG. 1.

FIG. 4 is a block diagram illustrating a voltage transforming module of the protecting circuit of the power amplifier according to FIG. 1.

FIG. 5 is a circuit diagram illustrating a DC-DC converter of the voltage transforming module of the protecting circuit of the power amplifier according to FIG. 4.

FIG. 6 is a circuit diagram illustrating another DC-DC converter of the voltage transforming module of the protecting circuit of the power amplifier according to FIG. 4.

FIG. 7 is a circuit diagram illustrating yet another DC-DC converter of the voltage transforming module of the protecting circuit of the power amplifier according to FIG. 4.

FIG. 8A is a circuit diagram illustrating a part of a level shifter of the voltage transforming module of the protecting circuit of the power amplifier according to FIG. 4.

FIG. 8B is a circuit diagram illustrating another part of the level shifter of the voltage transforming module of the protecting circuit of the power amplifier according to FIG. 4.

FIG. 8C is circuit diagram illustrating yet another part of the level shifter of the voltage transforming module of the protecting circuit of the power amplifier according to FIG. 4.

FIG. 9 is a block diagram illustrating an electronic device according to a second embodiment of the present disclosure.

FIG. 10 is a flowchart illustrating an adjusting method of supplying voltage according to a third embodiment of the present disclosure.

### DETAILED DESCRIPTION

The embodiment will be described with the drawings. For clarity, some practical details will be described below. However, it should be noted that the present disclosure should not be limited by the practical details, that is, in some embodiment, the practical details is unnecessary. In addition, for simplifying the drawings, some conventional structures and elements will be simply illustrated, and repeated elements may be represented by the same labels.

It will be understood that when an element (or device) is referred to as be “connected to” another element, it can be directly connected to the other element, or it can be indirectly connected to the other element, that is, intervening elements may be present. In contrast, when an element is referred to as be “directly connected to” another element, there are no intervening elements present. In addition, the terms first, second, third, etc. are used herein to describe various elements or components, these elements or components should not be limited by these terms. Consequently, a first element or component discussed below could be termed a second element or component.

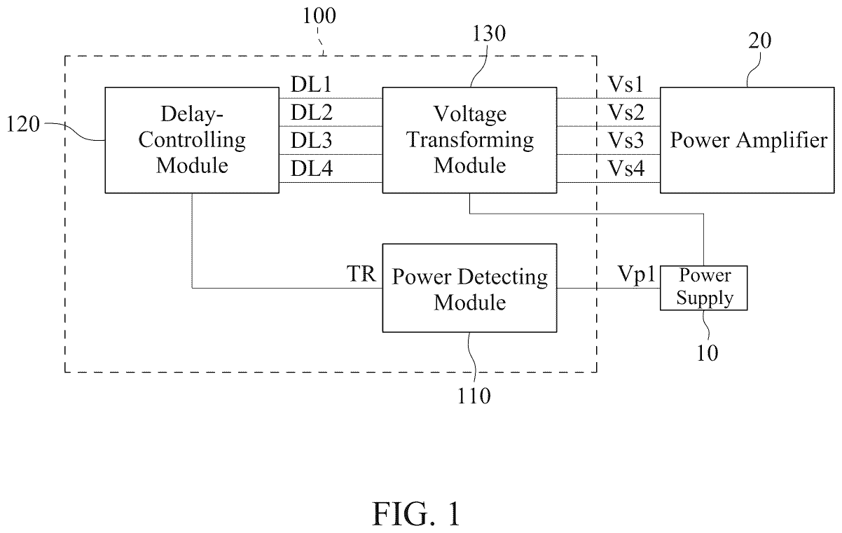

Referring to FIG. 1, which is a block diagram illustrating a protecting circuit 100 of a power amplifier 20 according to a first embodiment of the present disclosure. The protecting circuit 100 of the power amplifier 20 includes a power detecting module 110, a delay-controlling module 120, and a voltage transforming module 130. The power detecting module 110 is electrically connected to a power supply 10 and detects a power voltage Vp1 of the power supply 10. When the power voltage Vp1 is less than a predetermined level, the power detecting module 110 generates a trigger signal TR. The delay-controlling module 120 is electrically connected to the power detecting module 110 and receives the trigger signal TR. The delay-controlling module 120 is triggered by the trigger signal TR to generate a plurality of delay signals DL1, DL2, DL3, and DL4. The voltage transforming module 130 is electrically connected to the power supply 10 and the delay-controlling module 120. The voltage transforming module 130 receives the delay signals DL1, DL2, DL3, and DL4 and is configured to transform the power voltage Vp1 of the power supply 10 into a plurality of supplying voltages Vs1, Vs2, Vs3, and Vs4. The voltage transforming module 130 sequentially inputs the supplying voltages Vs1, Vs2, Vs3, and Vs4 to a plurality of supplying voltage pins of the power amplifier 20 according to the delay signals DL1, DL2, DL3, and DL4.

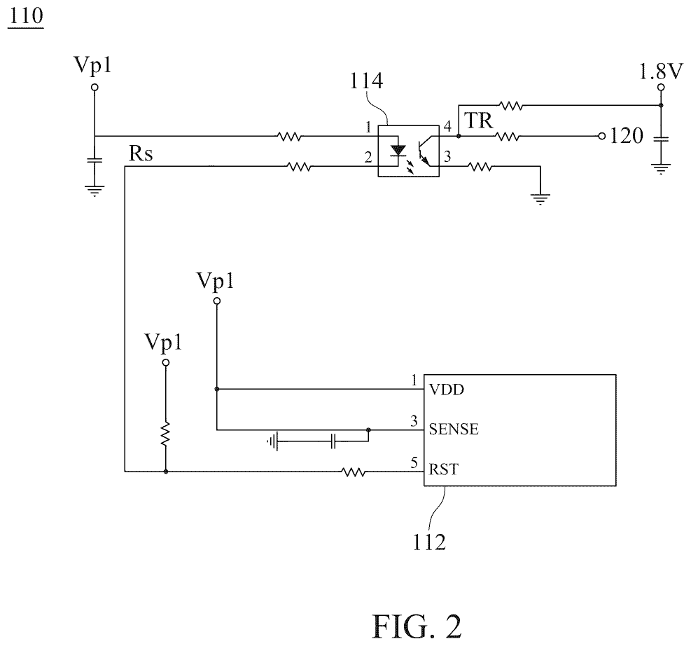

Referring to FIGS. 1 and 2, where FIG. 2 is a circuit diagram illustrating a power detecting module 110 of the protecting circuit 100 of the power amplifier 20 according to FIG. 1. The power detecting module 110 includes a resetter 112 and an optocoupler 114. The resetter 112 is electrically connected to the power supply 10 and detects the power voltage Vp1 of the power supply 10 to generate a reset signal Rs. The optocoupler 114 is electrically connected between the resetter 112 and the delay-controlling module 120. The optocoupler 114 receives the reset signal Rs and converts it into the trigger signal TR. Specifically, the resetter 112 can be a reset integrated circuit (reset IC). The sensing pin (i.e., pin SENSE) of the resetter 112 is connected to the power voltage Vp1, and the output pin (i.e., pin RST) is connected to the power voltage Vp1 through two resistors (not shown in the figure). When the sensing pin (i.e., pin SENSE) of the resetter 112 detects that the power voltage Vp1 is less than a predetermined value, the output pin (i.e., pin RST) of the resetter 112 outputs the reset signal Rs. Since the high and low voltage levels between the resetter 112 and the delay-controlling module 120 are different, the reset signal Rs output by the resetter 112 cannot be directly used as the trigger signal TR of the delay-controlling module 120. Therefore, the optocoupler 114 is arranged between the resetter 112 and the delay-controlling module 120 to adjust the high and low voltage levels between the resetter 112 and the delay-controlling module 120.

Further, the first pin of the optocoupler 114 is connected to the power voltage Vp1 through a resistor, and the second pin is connected to the pin RST of the resetter 112 through a resistor to receive the reset signal Rs. The third pin of the optocoupler 114 is connected to the ground through a resistor, and the fourth pin is connected to the delay-controlling module 120 through a resistor to transmit the trigger signal TR to the delay-controlling module 120. Additionally, the fourth pin is also connected in parallel to a resistor and a capacitor. From FIG. 2, it can be seen that when the reset signal Rs is at a low level, the trigger signal TR is also at a low level.

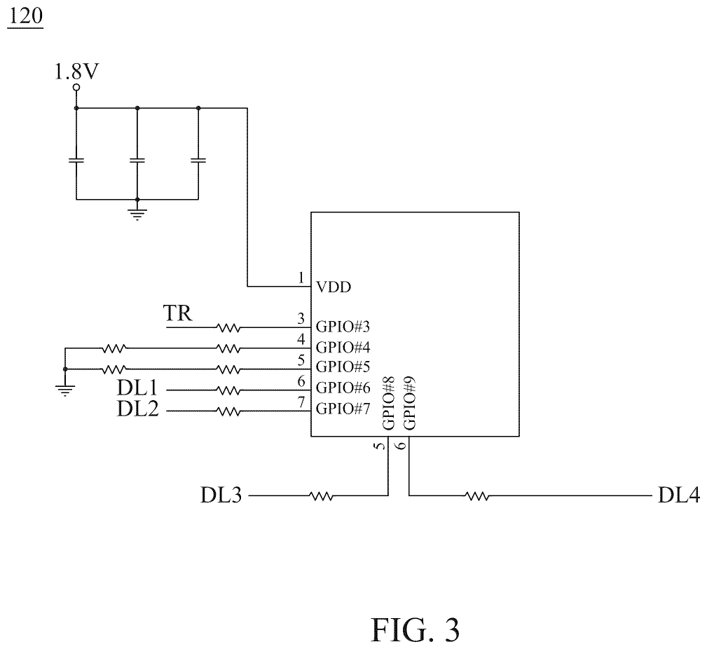

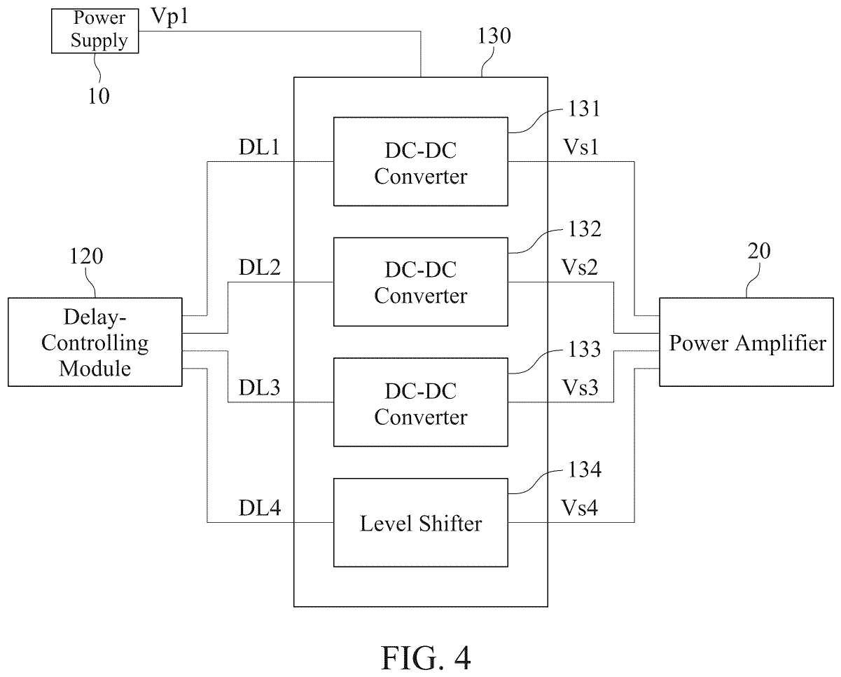

Referring to FIGS. 1 to 4, where FIG. 3 is a circuit diagram illustrating a delay-controlling module 120 of the protecting circuit 100 of the power amplifier 20 according to FIG. 1, and FIG. 4 is a block diagram illustrating a voltage transforming module 130 of the protecting circuit 100 of the power amplifier 20 according to FIG. 1. Specifically, the delay-controlling module 120 can be a Complex Programmable Logic Device (CPLD). In FIG. 4, the voltage transforming module 130 can include three DC-DC converters 131, 132, 133, and a level shifter 134, but the present disclosure is not limited thereto. For example, the supplying voltage Vs1 of the power amplifier 20 can be a 5-volt bias voltage, the supplying voltage Vs2 can be a −7.5-volt gate voltage, the supplying voltage Vs3 can be a −3.4-volt gate-source voltage, and the supplying voltage Vs4 can be a 28-volt drain voltage. The driving sequence of the supplying voltages Vs1, Vs2, Vs3, and Vs4 can be in the order of supplying voltages Vs1, Vs2, Vs3, and Vs4, and the shutdown sequence can be in the order of supplying voltages Vs4, Vs3, Vs2, and Vs1, but the present disclosure is not limited thereto. In FIG. 3, the pin VDD of the delay-controlling module 120 is connected to a capacitor and a 1.8-volt voltage. The pin GPIO #3 is used to detect the trigger signal TR, and the pins GPIO #4 and GPIO #5 are connected to the ground through resistors. When the trigger signal TR and the pin GPIO #5 are both at a high level, the pins GPIO #6, GPIO #7, GPIO #8, and GPIO #9 of the delay-controlling module 120 respectively output delay signals DL1, DL2, DL3, and DL4 to drive the power amplifier 20 to start. When either the trigger signal TR or the pin GPIO #5 is at a low level, the pins GPIO #6, GPIO #7, GPIO #8, and GPIO #9 of the delay-controlling module 120 respectively output delay signals DL1, DL2, DL3, and DL4 to drive the power amplifier 20 to shut down. Specifically, the starting of the delay-controlling module 120 at a high level or a low level is according to its specification setting, and the present disclosure is not limited thereto. The delay signals DL1, DL2, DL3, and DL4 are respectively used to control the driving sequence of the supplying voltages Vs1, Vs2, Vs3, and Vs4. Therefore, the protecting circuit 100 of the power amplifier 20 of the present disclosure can ensure that the supplying voltages Vs1, Vs2, Vs3, and Vs4 in the power amplifier 20 are shut down according to the specified time sequence when the power supply 10 is abnormally powered off, thereby avoiding the power amplifier 20 from being burned out.

In other embodiments of the present disclosure, the DC-DC converter and the level shifter can be interchanged or implemented by other voltage transforming circuits, but the present disclosure is not limited thereto.

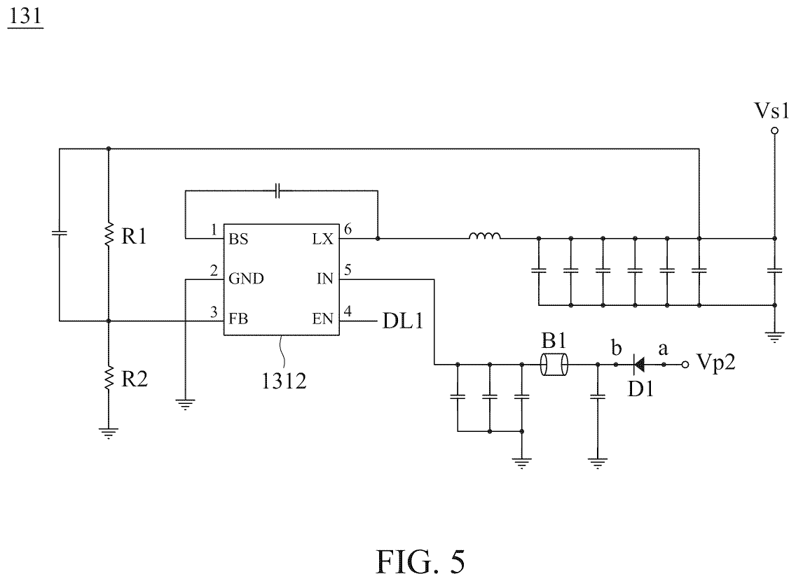

Referring to FIGS. 1, 4, and 5, where FIG. 5 is a circuit diagram illustrating a DC-DC converter 131 of the voltage transforming module 130 of the protecting circuit 100 of the power amplifier 20 according to FIG. 4. In FIG. 5, the DC-DC converter 131 can include a voltage source Vp2, a diode D1, and a buck circuit 1312. The diode D1 includes an anode terminal a and a cathode terminal b, where the anode terminal a is electrically connected to the voltage source Vp2. The voltage source Vp2 is connected to the buck circuit 1312 through the diode D1, a ferrite bead B1, and a capacitor. The buck circuit 1312 is electrically connected to the cathode terminal b of the diode D1 and is configured to convert the voltage source Vp2 into the supplying voltage Vs1, where the supplying voltage Vs1 is greater than zero. Specifically, the voltage source Vp2 is a 12-volt voltage required for the buck circuit 1312 converted by the power supply 10 through an additional transforming circuit (not shown in the figure). The pin BS and the pin LX of the buck circuit 1312 are connected through a capacitor, the pin GND is grounded, the pin IN receives the voltage source Vp2 through the diode D1, and the pin EN detects the delay signal DL1. When the delay signal DL1 is at a high level, the voltage source Vp2 is converted into a 5-volt supplying voltage Vs1 by the buck circuit 1312 and output by the pin LX. The resistance values of the resistors R1 and R2 connected to the pin FB can adjust the output voltage to the desired supplying voltage Vs1. The protecting circuit 100 of the power amplifier 20 of the present disclosure connects the diode D1 between the voltage source Vp2 and the supplying voltage Vs1 of the DC-DC converter 131, which can prevent the supplying voltage Vs1 generated by the buck circuit 1312 from being quickly consumed to zero along with the power off of the voltage source Vp2 when the power supply 10 is abnormally powered off.

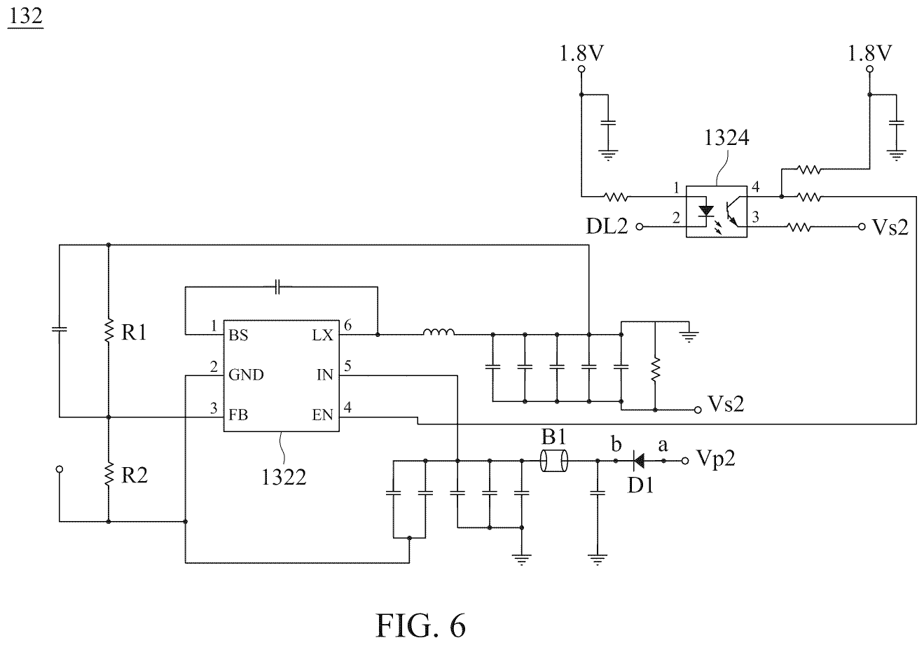

Referring to FIGS. 1, 4, and 6, where FIG. 6 is a circuit diagram illustrating a DC-DC converter 132 of the voltage transforming module 130 of the protecting circuit 100 of the power amplifier 20 according to FIG. 4. The DC-DC converter 132 can include a voltage source Vp2, a diode D1, a buck circuit 1322, and an optocoupler 1324. The diode D1 includes an anode terminal a and a cathode terminal b, where the anode terminal a is electrically connected to the voltage source Vp2. The voltage source Vp2 is connected to the buck circuit 1322 through the diode D1, a ferrite bead B1, and a capacitor. The buck circuit 1322 is electrically connected to the cathode terminal b of the diode D1 and is used to convert the voltage source Vp2 into the supplying voltage Vs2. The optocoupler 1324 is electrically connected to the buck circuit 1322 and the delay-controlling module 120 and receives the delay signal DL2. The optocoupler 1324 inputs the supplying voltage Vs2 to the power amplifier 20 according to the delay signal DL2, where the supplying voltage Vs2 is less than zero. Specifically, when the supplying voltage Vs2 is negative, the DC-DC converter 132 can more precisely control the output of the supplying voltage Vs2 through the optocoupler 1324 when the DC-DC converter 132 is triggered by the delay signal DL2. In FIG. 6, the first pin of the optocoupler 1324 is connected to a 1.8-volt voltage converted from the power supply 10 through a resistor and a capacitor, the second pin is connected to receive the delay signal DL2, the third pin outputs the supplying voltage Vs2, and the fourth pin is connected to the pin EN of the buck circuit 1322 and the 1.8-volt voltage converted from the power supply 10.

Furthermore, when the power supply 10 is normally supplying power, the delay signal DL2 input to the optocoupler 1324 is at a high level, and the pin EN of the buck circuit 1322 receives the 1.8-volt voltage from the optocoupler 1324, placing the buck circuit 1322 in an enable status. The pin LX of the buck circuit 1322 outputs the −7.5-volt supplying voltage Vs2 to the power amplifier 20. When the power supply 10 is abnormally powered off, the 1.8-volt voltage converted by the power supply 10 stops supplying power, and the fourth pin of the optocoupler 1324 switches from the 1.8-volt voltage to a negative voltage level, placing the pin EN of the buck circuit 1322 in a disable status. The pin LX of the buck circuit 1322 does not output voltage.

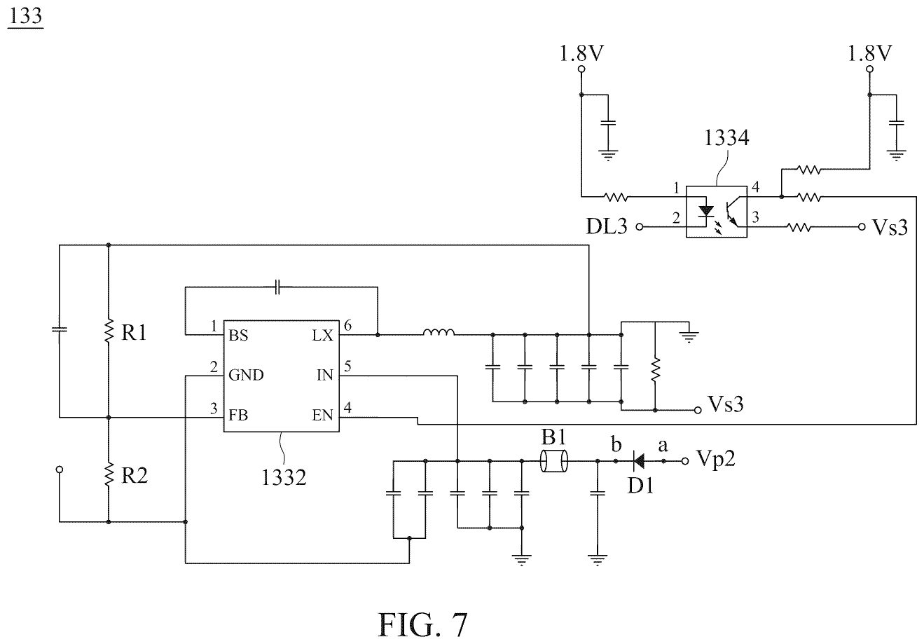

Referring to FIGS. 1, 4, and 7, where FIG. 7 is a circuit diagram illustrating a DC-DC converter 133 of the voltage transforming module 130 of the protecting circuit 100 of the power amplifier 20 according to FIG. 4. The DC-DC converter 133 can include a voltage source Vp2, a diode D1, a buck circuit 1332, and an optocoupler 1334. The diode D1 includes an anode terminal a and a cathode terminal b, where the anode terminal a is electrically connected to the voltage source Vp2. The voltage source Vp2 is connected to the buck circuit 1332 through the diode D1, a ferrite bead B1, and a capacitor. The buck circuit 1332 is electrically connected to the cathode terminal b of the diode D1 and is used to convert the voltage source Vp2 into the supplying voltage Vs3. The optocoupler 1334 is electrically connected to the buck circuit 1332 and the delay-controlling module 120 and receives the delay signal DL3. The optocoupler 1334 inputs the supplying voltage Vs3 to the power amplifier 20 according to the delay signal DL3, where the supplying voltage Vs3 is less than zero. The structure and mechanism of the optocoupler 1334 in FIG. 7 is the same as the optocoupler 1324 and therefore will not be described herein.

For example, when the power supply 10 is normally supplying power, the delay signal DL3 input to the optocoupler 1334 is at a high level, and the pin EN of the buck circuit 1332 receives the 1.8-volt voltage from the optocoupler 1334, placing the buck circuit 1332 in an enable status. The pin LX of the buck circuit 1332 outputs the −3.4-volt supplying voltage Vs3 to the power amplifier 20. When the power supply 10 is abnormally powered off, the 1.8-volt voltage converted by the power supply 10 stops supplying power, and the fourth pin of the optocoupler 1334 switches from the 1.8-volt voltage to a negative voltage level, placing the pin EN of the buck circuit 1332 in a disable status. The pin LX of the buck circuit 1332 does not output voltage.

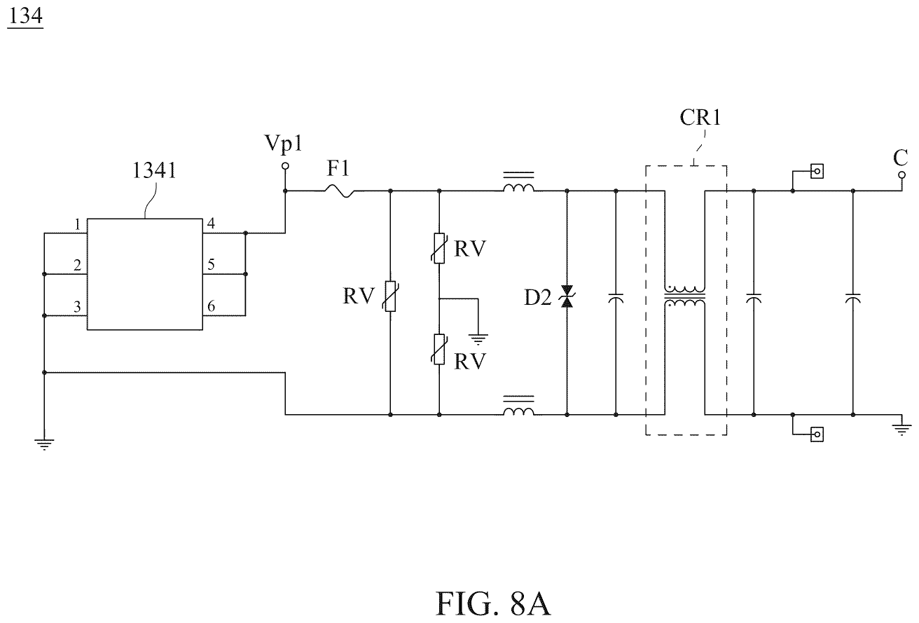

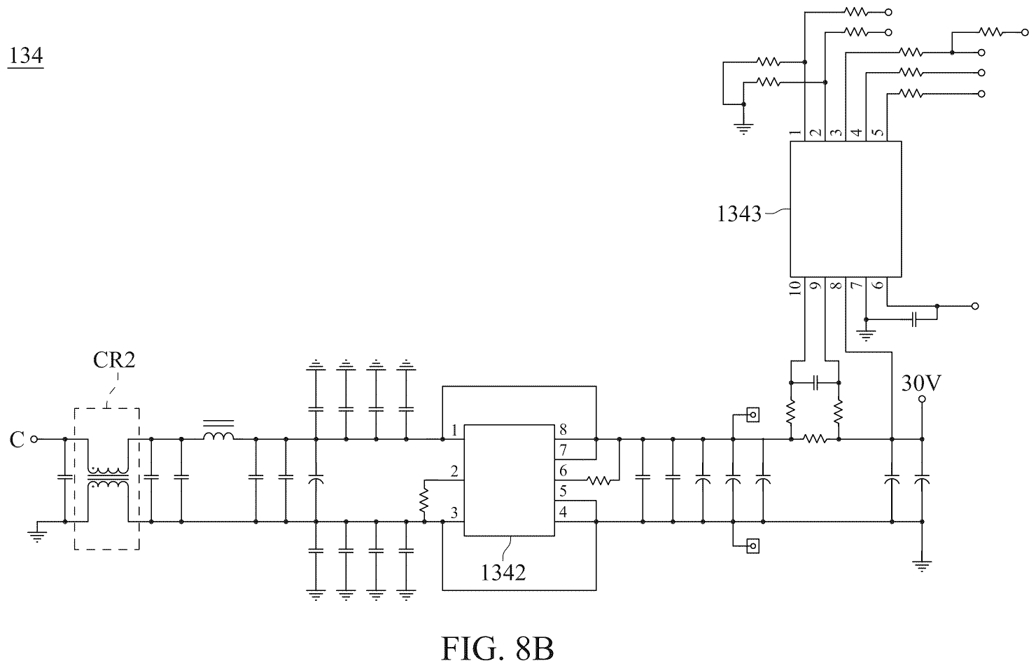

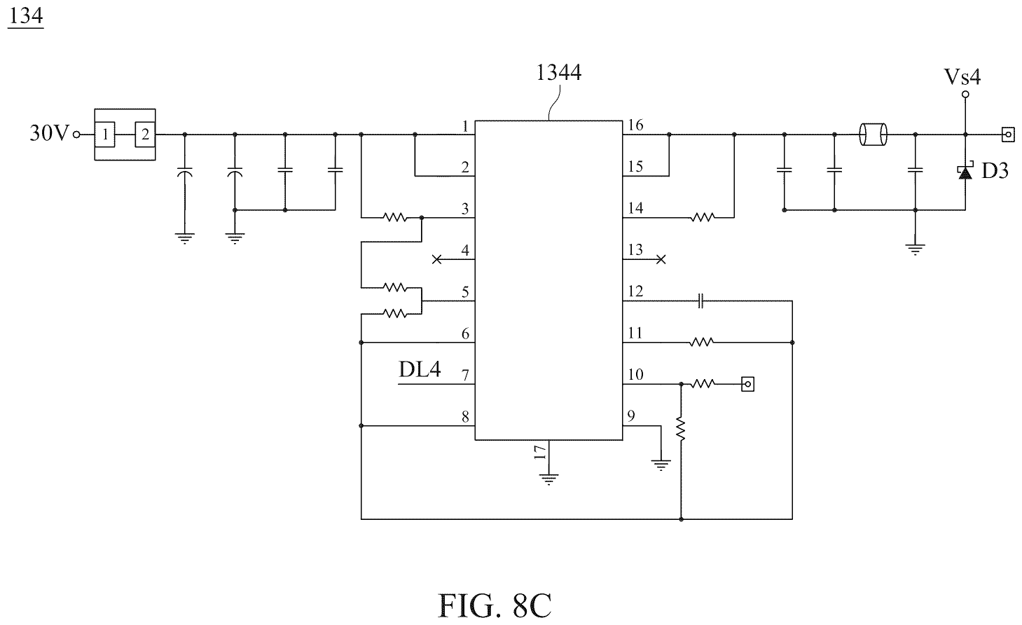

Referring to FIGS. 1, 4, 8A, 8B, and 8C, where FIGS. 8A, 8B, and 8C are circuit diagrams illustrating different parts of a level shifter 134 of the voltage transforming module 130 of the protecting circuit 100 of the power amplifier 20 according to FIG. 4, and FIGS. 8A, 8B, and 8C together constitute the level shifter 134 of the voltage transforming module 130 of the protecting circuit 100 of the power amplifier 20 shown in FIG. 4. The level shifter 134 is electrically connected to the delay-controlling module 120, the power supply 10, and the power amplifier 20, and is used to convert the power supply 10 into the supplying voltage Vs4. As shown in FIGS. 8A, 8B, and 8C, the level shifter 134 includes a connector 1341, an isolated DC-DC converter 1342, a current detector 1343, and a voltage controller 1344. In FIG. 8A, the connector 1341 is connected to the power voltage Vp1. The power voltage Vp1 is connected to the terminal C through a fuse F1, a variable resistor RV, a diode D2, a transformer CR1, and a capacitor. In FIG. 8B, the power voltage Vp1 converted by the transformer CR1 in FIG. 8A is converted, from the terminal C through the transformer CR2, a capacitor, an inductor, the isolated DC-DC converter 1342, and the current detector 1343, to a 30-volt voltage. In FIG. 8C, the voltage controller 1344 is used to convert the 30-volt voltage to the 28-volt voltage required by the supplying voltage Vs4. The seventh pin of the voltage controller 1344 is connected to the delay-controlling module 120 to receive the delay signal DL4. The voltage controller 1344 outputs the supplying voltage Vs4 through a capacitor and the diode D3 according to the delay signal DL4.

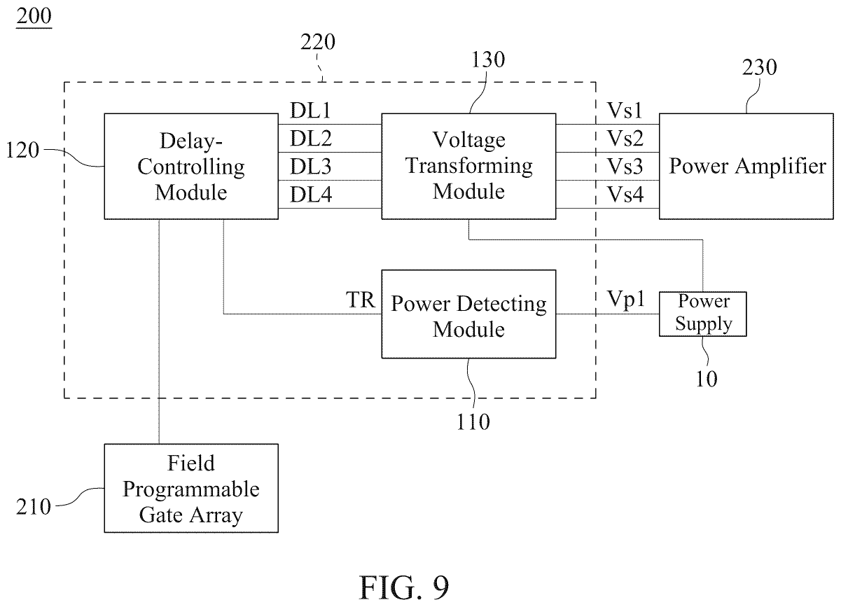

Referring to FIGS. 1 and 9 together, where FIG. 9 is a block diagram illustrating an electronic device 200 according to a second embodiment of the present disclosure. The electronic device 200 includes a Field Programmable Gate Array (FPGA) 210, a protecting circuit 220, and a power amplifier 230. In the second embodiment, the protecting circuit 220 can operate similarly to the protecting circuit 100 of the power amplifier 20 in the first embodiment, and therefore, it will not be described herein. The electronic device 200 can be an RRU in an Open-Radio Access Network (O-RAN) architecture. The electronic device 200 can further include a radio frequency integrated circuit (not shown), a low noise amplifier (LNA) module (not shown), a transceiver matching circuit (not shown), a transceiver (not shown), and a transmitter (not shown), but the present disclosure is not limited thereto. The radio frequency integrated circuit, the LNA module, and the power amplifier 230 can be controlled by the FPGA 210.

Additionally, the power detecting module 110, the delay-controlling module 120, and the voltage transforming module 130 can be electrically connected to a capacitor with a large capacitance value (not shown), ensuring that the protecting circuit 220 retains enough time to shut down the power amplifier 230 according to the specified time sequence when the power supply 10 is abnormally powered off, thereby avoiding damage to the power amplifier 230 and reducing the maintenance cost of the electronic device 200.

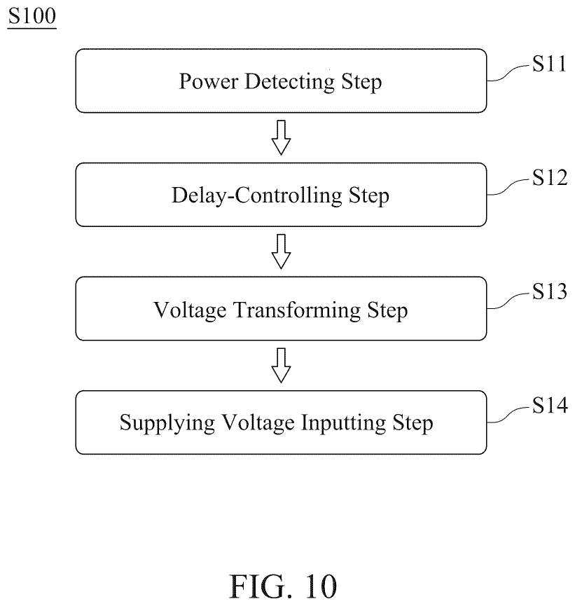

Referring to FIGS. 1 and 10, where FIG. 10 is a flowchart illustrating an adjusting method S100 of supplying voltage according to a third embodiment of the present disclosure. The adjusting method S100 of supplying voltage includes a power detecting step S11, a delay-controlling step S12, a voltage transforming step S13, and a supplying voltage inputting step S14. The power detecting step S11 includes driving a power detecting module 110 to detect a power voltage Vp1 of a power supply 10 and generating a trigger signal TR when the power voltage Vp1 is less than a predetermined level. The delay-controlling step S12 includes driving a delay-controlling module 120 to generate a plurality of delay signals DL1, DL2, DL3, and DL4 according to the trigger signal TR. The voltage transforming step S13 includes driving a voltage transforming module 130 to transform the power voltage Vp1 of the power supply 10 into a plurality of supplying voltages Vs1, Vs2, Vs3, and Vs4. The supplying voltage inputting step S14 includes driving the voltage transforming module 130 to sequentially input the supplying voltages Vs1, Vs2, Vs3, and Vs4 to a power amplifier 20 according to the delay signals DL1, DL2, DL3, and DL4.

Referring to FIGS. 2 and 10, where the power detecting step S11 can further include driving a resetter 112 to detect the power voltage Vp1 of the power supply 10 to generate a reset signal Rs and driving an optocoupler 114 to receive the reset signal Rs and convert it into the trigger signal TR.

Referring to FIGS. 5 and 10, where the voltage transforming step S13 can further include driving a buck circuit 1312 to convert the voltage source Vp2 into the supplying voltage Vs1, which is greater than zero.

Referring to FIGS. 6 and 10, where the voltage transforming step S13 can further include driving a buck circuit 1322 to convert the voltage source Vp2 into the supplying voltage Vs2 and driving an optocoupler 1324 to receive the delay signal DL2 and input the supplying voltage Vs2 to the power amplifier 20 according to the delay signal DL2. Thus, the adjusting method S100 for supplying voltage of the present disclosure automatically controls the on-off sequence of the plurality of supplying voltages Vs1, Vs2, Vs3, and Vs4 of the power amplifier 20 in a very short time, reducing the time for manually turning on and off the plurality of supplying voltages Vs1, Vs2, Vs3, and Vs4, and also avoiding human errors in manual operations.

In view of the above, the protecting circuit of the power amplifier, the adjusting method of supplying voltage, and the electronic device of the present disclosure have the following advantages. First, the protecting circuit can ensure that the supplying voltages in the power amplifier are shut down according to the specified time sequence when the power supply is abnormally powered off, thereby avoiding the power amplifier from being burned out. Second, it avoids damage to the power amplifier in the electronic device, thereby reducing the maintenance cost of the electronic device. Third, the sequence control module automatically controls the on-off sequence of multiple supplying voltages in a very short time, reducing the time for manually turning on and off multiple supplying voltages and avoiding human errors in manual operations.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A protecting circuit of a power amplifier, comprising:
a power detecting module, electrically connected to a power supply and detecting a power voltage of the power supply, wherein when the power voltage is less than a predetermined level, the power detecting module generates a trigger signal;
a delay-controlling module, electrically connected to the power detecting module and receiving the trigger signal, wherein the delay-controlling module is triggered by the trigger signal to generate a plurality of delay signals; and
a voltage transforming module, electrically connected to the power supply and the delay-controlling module and receiving the plurality of delay signals, wherein the voltage transforming module is configured to transform the power voltage of the power supply into a plurality of supplying voltages;
wherein the voltage transforming module sequentially inputs the plurality of supplying voltages to the power amplifier according to the plurality of delay signals.

2. The protecting circuit of the power amplifier as claimed in claim 1, wherein the power detecting module comprises:
a resetter, electrically connected to the power supply and detecting the power voltage of the power supply to generate a reset signal; and
an optocoupler, electrically connected between the resetter and the delay-controlling module, wherein the optocoupler receives the reset signal and converts the reset signal into the trigger signal.

3. The protecting circuit of the power amplifier as claimed in claim 1, wherein the delay-controlling module is a complex programmable logic device.

4. The protecting circuit of the power amplifier as claimed in claim 1, wherein the voltage transforming module comprises at least one of at least one DC-DC converter and at least one level shifter.

5. The protecting circuit of the power amplifier as claimed in claim 4, wherein the at least one DC-DC converter comprises:
a voltage source;
a diode, comprising an anode terminal and a cathode terminal, wherein the anode terminal is electrically connected to the voltage source; and
a buck circuit, electrically connected to the cathode terminal of the diode and configured to convert the voltage source into one of the plurality of supplying voltages, wherein the one of the plurality of supplying voltages is greater than zero.

6. The protecting circuit of the power amplifier as claimed in claim 4, wherein the at least one DC-DC converter comprises:
a voltage source;
a diode, comprising an anode terminal and a cathode terminal, wherein the anode terminal is electrically connected to the voltage source;
a buck circuit, electrically connected to the cathode terminal of the diode and configured to convert the voltage source into one of the plurality of supplying voltages; and
an optocoupler, electrically connected to the buck circuit and the delay-controlling module, wherein the optocoupler receives one of the plurality of delay signals and inputs the one of the plurality of supplying voltages to the power amplifier according to the one of the plurality of delay signals, wherein the one of the plurality of supplying voltages is less than zero.

7. The protecting circuit of the power amplifier as claimed in claim 4, wherein the at least one level shifter electrically connects the delay-controlling module, the power supply, and the power amplifier, and is configured to transform the power supply into at least one of the plurality of supplying voltages.

8. An adjusting method of supplying voltage, comprising:
a power detecting step, comprising driving a power detecting module to detect a power voltage of a power supply and generating a trigger signal when the power voltage is less than a predetermined level;
a delay-controlling step, comprising driving a delay-controlling module to generate a plurality of delay signals according to the trigger signal;
a voltage transforming step, comprising driving a voltage transforming module to transform the power voltage of the power supply into a plurality of supplying voltages; and
a supplying voltage inputting step, comprising driving the voltage transforming module to sequentially input the plurality of supplying voltages to a power amplifier according to the plurality of delay signals.

9. The adjusting method of supplying voltage as claimed in claim 8, wherein the power detecting step further comprises:
driving a resetter to detect the power voltage of the power supply to generate a reset signal; and
driving an optocoupler to receive the reset signal and convert the reset signal into the trigger signal;
wherein the resetter is electrically connected to the optocoupler, and the optocoupler is electrically connected to the delay-controlling module.

10. The adjusting method of supplying voltage as claimed in claim 8, wherein the delay-controlling module is a complex programmable logic device.

11. The adjusting method of supplying voltage as claimed in claim 8, wherein the voltage transforming step further comprises:
driving a buck circuit to convert a voltage source into one of the plurality of supplying voltages;
wherein the one of the plurality of supplying voltages is less than zero.

12. The adjusting method of supplying voltage as claimed in claim 8, wherein the voltage transforming step further comprises:
driving a buck circuit to convert a voltage source into one of the plurality of supplying voltages; and
driving an optocoupler to input the one of the plurality of supplying voltages to the power amplifier according to one of the plurality of delay signals;
wherein the one of the plurality of supplying voltages is less than zero.

13. An electronic device, comprising:
a field programmable gate array;
a protecting circuit, comprising:
a power detecting module, electrically connected to a power supply and detecting a power voltage of the power supply, wherein when the power voltage is less than a predetermined level, the power detecting module generates a trigger signal;
a delay-controlling module, electrically connected to the field programmable gate array and the power detecting module and receiving the trigger signal, wherein the delay-controlling module is triggered by the trigger signal to generate a plurality of delay signals; and
a voltage transforming module, electrically connected to the power supply and the delay-controlling module and receiving the plurality of delay signals, wherein the voltage transforming module is configured to transform the power voltage of the power supply into a plurality of supplying voltages; and
a power amplifier, electrically connected to the voltage transforming module and comprising a plurality of supplying voltage pins, wherein the plurality of supplying voltage pins receive the plurality of supplying voltages, and the power amplifier is driven by the plurality of supplying voltages;
wherein the voltage transforming module sequentially inputs the plurality of supplying voltages to the supplying voltage pins according to the plurality of delay signals.

14. The electronic device as claimed in claim 13, wherein the power detecting module comprises:
a resetter, electrically connected to the power supply and detecting the power voltage of the power supply to generate a reset signal; and
an optocoupler, electrically connected between the resetter and the delay-controlling module, wherein the optocoupler receives the reset signal and converts the reset signal into the trigger signal.

15. The electronic device as claimed in claim 13, wherein the delay-controlling module is a complex programmable logic device.

16. The electronic device as claimed in claim 13, wherein the voltage transforming module comprises at least one of at least one DC-DC converter and at least one level shifter.

17. The electronic device as claimed in claim 16, wherein, when one of the plurality of supplying voltages is greater than zero, the at least one DC-DC converter comprises:
a voltage source;
a diode, comprising an anode terminal and a cathode terminal, wherein the anode terminal is electrically connected to the voltage source; and
a buck circuit, electrically connected to the cathode terminal of the diode and configured to convert the voltage source into the one of the plurality of supplying voltages.

18. The electronic device as claimed in claim 16, wherein, when one of the plurality of supplying voltages is less than zero, the at least one DC-DC converter comprises:
a voltage source;
a diode, comprising an anode terminal and a cathode terminal, wherein the anode terminal is electrically connected to the voltage source;
a buck circuit, electrically connected to the cathode terminal of the diode and configured to convert the voltage source into the one of the plurality of supplying voltages; and
an optocoupler, electrically connected to the buck circuit and the delay-controlling module, wherein the optocoupler receives one of the plurality of delay signals and inputs the one of the plurality of supplying voltages to the power amplifier according to the one of the plurality of delay signals.

19. The electronic device as claimed in claim 16, wherein the at least one level shifter electrically connects the delay-controlling module, the power supply, and the power amplifier, and is configured to transform the power supply into at least one of the plurality of supplying voltages.
